(19) United States
(12) Patent Application Publication
(10) Pub. No.: US 2024/0312771 A1
(43) Pub. Date: Sep. 19, 2024

(54) ETCHING METHOD, PLASMA PROCESSING APPARATUS, AND SUBSTRATE PROCESSING SYSTEM

(71) Applicant: Tokyo Electron Limited, Tokyo (JP)

(72) Inventors: Yusuke TAKINO, Miyagi (JP); Noboru SAITO, Miyagi (JP); Takahiro YOKOYAMA, Miyagi (JP)

(73) Assignee: Tokyo Electron Limited, Tokyo (JP)

(21) Appl. No.: 18/603,584

(22) Filed: Mar. 13, 2024

(30) Foreign Application Priority Data
Mar. 13, 2023 (JP) 2023-038460
Feb. 26, 2024 (JP) 2024-026375

(51) Int. Cl. H01J 37/32; H01L 21/3065; H01L 21/311

(52) U.S. Cl. CPC H01J 37/32724; H01J 37/32449; H01L 21/3065; H01L 21/31116; H01J 2237/334

(57) ABSTRACT

An etching method includes: (a) providing a substrate having a film stack including at least two different silicon-containing films and a mask on the film stack; (b) etching the film stack using plasma generated from a first processing gas to form a recess in the film stack; and (c) supplying hydrogen fluoride to the recess in the film stack.

### CROSS-REFERENCE TO RELATED APPLICATIONS

This application is based on and claims priority from Japanese Patent Application Nos. 2023-038460 and 2024-026375, filed on Mar. 13, 2023 and Feb. 26, 2024, respectively, with the Japan Patent Office, the disclosures of each are incorporated herein in their entireties by reference.

### TECHNICAL FIELD

An embodiment of the present disclosure relates to an etching method, a plasma processing apparatus, and a substrate processing system.

### BACKGROUND

International Patent Publication WO 2014/069559 discloses a technique for etching a film stack by generating plasma from a processing gas containing a CF-based gas and an oxygen gas.

### SUMMARY

An embodiment of the present disclosure provides a method of etching including: (a) providing a substrate having a film stack including at least two different silicon-containing films and a mask on the film stack; (b) etching the film stack using plasma generated from a first processing gas to form a recess in the film stack; and (c) supplying hydrogen fluoride to the recess in the film stack.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating a configuration example of a plasma processing apparatus.

FIG. 2 is a view illustrating a configuration example of a capacitively coupled plasma processing apparatus.

FIG. 3 is a flowchart illustrating an example of the present method.

FIG. 4 is a view illustrating an example of the cross-sectional structure of a substrate W provided in step ST1.

FIG. 5 is a view illustrating an example of the cross-sectional structure of the substrate W after the processing in step ST2.

FIG. 6 is a view illustrating an example of the cross-sectional structure of the substrate W after the processing in step ST3.

FIG. 7 is a graph showing an example of an adsorption equilibrium pressure curve of hydrogen fluoride.

FIG. 8 is a view illustrating a configuration example of a substrate processing system PS1.

FIG. 9 is a view illustrating a configuration example of a substrate processing system PS2.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, each embodiment of the present disclosure will be described.

An embodiment provides an etching method. The etching method includes: (a) providing a substrate having a film stack including at least two different silicon-containing films and a mask on the film stack; (b) etching the film stack using plasma generated from a first processing gas to form a recess in the film stack; and (c) supplying hydrogen fluoride to the recess in the film stack.

In an embodiment, the film stack includes at least two films selected from the group consisting of a silicon oxide film, a silicon nitride film, and a polysilicon film.

In an embodiment, the film stack is formed by alternately stacking a silicon oxide film and a silicon nitride film a plurality of times.

In an embodiment, the mask is a carbon-containing film or a metal-containing film.

In an embodiment, the first processing gas contains hydrogen fluoride gas.

In an embodiment, the first processing gas contains at least one gas selected from the group consisting of hydrogen fluoride gas, hydrofluorocarbon gas, and a mixed gas of a hydrogen-containing gas and a fluorine-containing gas.

In an embodiment, the first processing gas further contains a phosphorus-containing gas.

In an embodiment, the first processing gas further contains at least one gas selected from the group consisting of a carbon-containing gas, an oxygen-containing gas, and a metal-containing gas.

In an embodiment, at the end of (b), the recess has a first opening size and a second opening size different from the first opening size alternately along a depth direction of the recess.

In an embodiment, the difference between the first opening size and the second opening size is 0.2 nm or more.

In an embodiment, (a) includes disposing the substrate within a first chamber, (b) includes supplying the first processing gas into the first chamber to generate the plasma, and (c) includes supplying a second processing gas containing hydrogen fluoride gas into the first chamber.

In an embodiment, (c) includes: (c1) controlling a temperature of the substrate or a substrate support unit that supports the substrate to a first temperature, and controlling a partial pressure of the hydrogen fluoride gas within the chamber to a first pressure; and (c2) after (c1), controlling the temperature of the substrate or the substrate support to a second temperature, and controlling the partial pressure of the hydrogen fluoride gas within the chamber to a second pressure. The second temperature is higher than the first temperature, and/or the second pressure is lower than the first pressure.

In an embodiment, (c) includes: (c1) controlling a temperature of the substrate or a substrate support unit that supports the substrate to a first temperature, and controlling a partial pressure of the hydrogen fluoride gas within the chamber to a first pressure; and (c2) after (c1), controlling the temperature of the substrate or the substrate support unit to a second temperature, and controlling the partial pressure of the hydrogen fluoride gas within the chamber to a second pressure. In a graph showing an adsorption equilibrium pressure curve of hydrogen fluoride where a horizontal axis represents temperature and a vertical axis represents pressure, the first temperature and the first pressure are located in a first region above the adsorption equilibrium pressure curve, the second temperature and the second pressure are located in a second region below the adsorption equilibrium pressure curve.

In an embodiment, (a) includes disposing the substrate within a first chamber, (b) includes supplying the first processing gas into the first chamber to generate the plasma, and (c) includes transferring the substrate from the first chamber to a second chamber different from the first chamber, and supplying a second processing gas containing hydrogen fluoride gas into the second chamber.

In an embodiment, the temperature of the substrate or the substrate support unit that supports the substrate in (c) is controlled to be lower than the temperature of the substrate or the substrate support unit that supports the substrate in (b).

In an embodiment, the second processing gas further contains a phosphorus-containing gas.

In an embodiment, (a) includes disposing the substrate within a first chamber, (b) includes supplying the first processing gas into the first chamber to generate the plasma, and (c) includes transferring the substrate to the outside of the first chamber, and supplying a processing liquid containing hydrogen fluoride to the substrate from the outside the first chamber.

In an embodiment, the processing liquid contains hydrofluoric acid (DHF) or buffered hydrofluoric acid (BHF).

In an embodiment, (a) includes disposing the substrate within a first chamber of a plasma processing system, (b) includes supplying the first processing gas into the first chamber to generate the plasma, and (c) includes transferring the substrate to a substrate processing apparatus outside the plasma processing system, and supplying hydrogen fluoride to the recess in the film stack within the substrate processing apparatus.

An embodiment further includes setting conditions of (c) based on data indicating a shape of the recess in the film stack.

In an embodiment, the conditions include at least one selected from the group consisting of a pressure of the chamber in which the substrate is accommodated, a temperature of the substrate or a substrate support unit that supports the substrate, and a flow rate of the hydrogen fluoride gas.

In an embodiment, (c) includes: (c3) supplying the hydrogen fluoride to the recess in the film stack under a first condition; and (c4) supplying the hydrogen fluoride to the recess in the film stack under a second condition different from the first condition.

In an embodiment, the second condition is different from the first condition in at least one selected from the group consisting of a pressure of the chamber in which the substrate is accommodated, a temperature of the substrate or a substrate support unit that supports the substrate, and a flow rate of the hydrogen fluoride gas.

An embodiment provides a plasma processing apparatus having a chamber, a plasma generation unit, a gas supply unit, and a control unit. The control unit is configured to execute a process including: (a) providing a substrate having a film stack including at least two different silicon-containing films and a mask on the film stack; (b) etching the film stack using plasma generated from a first processing gas to form a recess in the film stack; and (c) supplying hydrogen fluoride to the recess in the film stack. An embodiment provides a substrate processing system having a first chamber, a plasma generation unit, a second chamber, a gas supply unit, and a control unit. The control unit is configured to execute a process including: (a) providing the first chamber with a substrate having a film stack including at least two different silicon-containing films and a mask on the film stack; (b) etching the film stack using plasma generated from a first processing gas by the plasma generation unit within the first chamber to form a recess in the film stack; and (c) transferring the substrate from the first chamber to the second chamber, and supply, within the second chamber, a second processing gas containing hydrogen fluoride gas to the recess in the film stack by the gas supply unit.

Hereinafter, each embodiment will be described in detail with reference to the drawings. In each drawing, the same or similar elements are denoted by the same reference numerals, and redundant descriptions will be omitted. Unless otherwise specified, positional relationships such as top, bottom, left, and right will be described based on the positional relationships illustrated in the drawings. The dimensional ratios in the drawings do not indicate the actual ratios, and the actual ratios are not limited to the ratios illustrated in the drawings.

### Configuration Example of Plasma Processing Apparatus

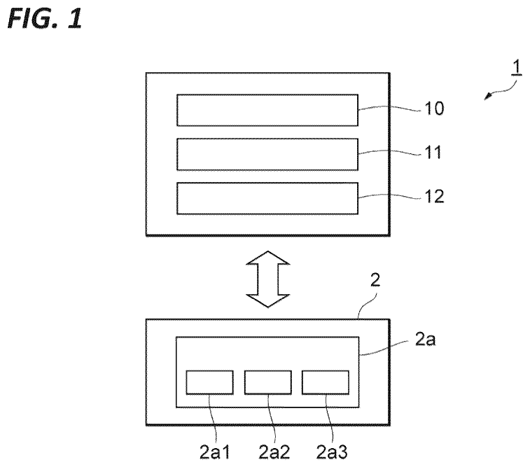

FIG. 1 is a view illustrating a configuration example of a plasma processing apparatus. In an embodiment, a plasma processing apparatus 1 configured as part of a substrate processing system includes a control unit 2, a plasma processing chamber 10, a substrate support unit 11, and a plasma generation unit 12. The plasma processing chamber 10 has a plasma processing space. In addition, the plasma processing chamber 10 has at least one gas supply port configured to supply at least one processing gas to the plasma processing space, and at least one gas discharge port configured to discharge gas from the plasma processing space. The gas supply port is connected to a gas supplier 20 to be described later, and the gas discharge port is connected to an exhaust system 40 to be described later. The substrate support unit 11 is arranged in the plasma processing space and has a substrate support surface that supports a substrate.

The plasma generation unit 12 is configured to generate plasma from at least one processing gas supplied into the plasma processing space. The plasma formed in the plasma processing space may be capacitively coupled plasma (CCP), inductively coupled plasma (ICP), electron-cyclotron-resonance (ECR) plasma, helicon wave plasma (HWP), surface wave plasma (SWP), or the like. In addition, various types of plasma generation units including an alternating current (AC) plasma generation unit and a direct current (DC) plasma generation unit may be used. In an embodiment, an AC signal (AC power) used in the AC plasma generation unit has a frequency in the range of 100 kHz to 10 GHz. Therefore, the AC signal includes a radio frequency (RF) signal and a microwave signal. In an embodiment, the RF signal has a frequency within the range of 100 kHz to 150 MHz.

The control unit 2 processes computer-executable instructions that cause the plasma processing apparatus 1 to execute various steps described in the present disclosure. The control unit 2 may be configured to control each element of the plasma processing apparatus 1 to execute various steps described herein. In an embodiment, a part or all of the control unit 2 may be configured as a system outside the plasma processing apparatus 1. The control unit 2 may include a processing unit 2a1, a storage unit 2a2, and a communication interface 2a3. The control unit 2 is implemented by, for example, a computer 2a. The processing unit 2a1 may be configured to perform various control operations by reading a program from the storage unit 2a2 and executing the read program. This program may be stored in the storage unit 2a2 in advance, or may be acquired via a medium when necessary. The acquired program is stored in the storage unit 2a2 to be read from the storage unit 2a2 and executed by the processing unit 2a1. The medium may be various storage media readable by the computer 2a, or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with each element of the plasma processing apparatus 1 via a communication line such as a local area network (LAN).

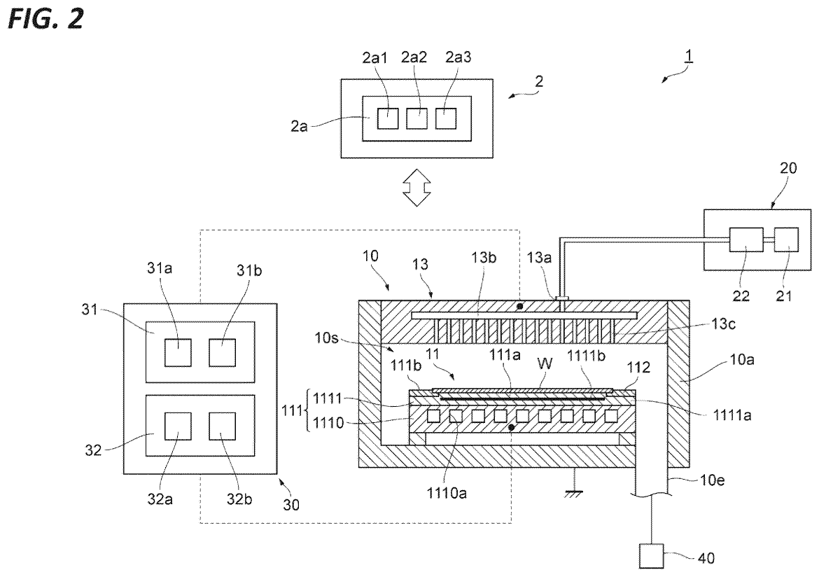

A configuration example of a capacitively coupled plasma processing apparatus as an example of the plasma processing apparatus 1 will be described below. FIG. 2 is a view illustrating a configuration example of a capacitively coupled plasma processing apparatus.

The capacitively coupled plasma processing apparatus 1 includes a control unit 2, a plasma processing chamber 10, a gas supply unit 20, a power supply 30, and an exhaust system 40. In addition, the plasma processing apparatus 1 includes a substrate support unit 11 and a gas injector. The gas injector is configured to inject at least one processing gas into the plasma processing chamber 10. The gas injector includes a shower head 13. The substrate support unit 11 is disposed in the plasma processing chamber 10. The shower head 13 is disposed above the substrate support unit 11. In an embodiment, the shower head 13 constitutes at least a portion of the ceiling of the plasma processing chamber 10. The plasma processing chamber 10 has a plasma processing space 10s defined by the shower head 13, the side wall 10a of the plasma processing chamber 10, and the substrate support unit 11. The plasma processing chamber 10 is grounded. The shower head 13 and the substrate support unit 11 are electrically insulated from the housing of the plasma processing chamber 10.

The substrate support unit 11 includes a main body 111 and a ring assembly 112. The main body 111 has a central region 111a that supports a substrate W and an annular region 111b that supports the ring assembly 112. A wafer is an example of the substrate W. The annular region 111b of the main body 111 surrounds the central region 11la of the main body 111 in a plan view. The substrate W is placed on the central region 111a of the main body 111, and the ring assembly 112 is disposed on the annular region 111b of the main body 111 to surround the substrate W on the central region 11la of the main body 111. Accordingly, the central region 11la is also referred to as a “substrate support surface” that supports the substrate W, and the annular region 111b is also referred to as a “ring support surface” that supports the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 11la. In an embodiment, the ceramic member 1111a also has an annular region 111b. In addition, another member surrounding the electrostatic chuck 1111, such as an annular electrostatic chuck or an annular insulating member, may have the annular region 111b. In this case, the ring assembly 112 may be placed on the annular electrostatic chuck or the annular insulating member, or may be placed on both the electrostatic chuck 1111 and the annular insulating member. In addition, at least one RF/DC electrode coupled to an RF power supply 31 and/or a DC power supply 32 to be described below may be disposed within the ceramic member 1111a. In this case, the at least one RF/DC electrode functions as the lower electrode. When a bias RF signal and/or a DC signal to be described below is supplied to the at least one RF/DC electrode, the RF/DC electrode is also referred to as a “bias electrode.” In addition, the conductive member of the base 1110 and the at least one RF/DC electrode may function as a plurality of lower electrodes. Furthermore, the electrostatic electrode 1111b may function as a lower electrode. Accordingly, the substrate support unit 11 includes at least one lower electrode.

The ring assembly 112 includes one or more annular members. In an embodiment, the one or more annular members include one or more edge rings and at least one cover ring. The edge rings are made of a conductive material or an insulating material, and the cover ring is made of an insulating material.

In addition, the substrate support unit 11 may include a temperature regulating module configured to regulate at least one of the electrostatic chuck 1111, the ring assembly 112, and the substrate to a target temperature. The temperature regulating module may include a heater, a heat transfer medium, a flow path 1110a, or a combination thereof. A heat transfer fluid, such as brine or gas, flows through the flow path 1110a. In an embodiment, the flow path 1110a is formed in the base 1110, and one or more heaters are disposed in the ceramic member 1111a of electrostatic chuck 1111. In addition, the substrate support unit 11 may include a heat transfer gas supply unit configured to supply a heat transfer gas to the gap between the rear surface of the substrate W and the central region 111a.

The shower head 13 is configured to inject at least one processing gas from the gas supplier 20 into the plasma processing space 10s. The shower head 13 has at least one gas supply port 13a, at least one gas diffusion chamber 13b, and a plurality of gas injection ports 13c. The processing gas supplied to the gas supply port 13a passes through the gas diffusion chamber 13b and is injected into the plasma processing space 10s from the plurality of gas introduction ports 13c. In addition, the shower head 13 includes at least one upper electrode. In addition to the shower head 13, the gas injector may include a single side gas injector (SGI) or multiple side gas injectors installed in one opening or multiple openings formed in the side wall 10a.

The gas supply unit 20 may include at least one gas source 21 and at least one flow rate controller 22. In an embodiment, the gas supply unit 20 is configured to supply at least one processing gas from a corresponding gas source 21 to the shower head 13 via the corresponding flow rate controller 22. Each flow rate controller 22 may include, for example, a mass flow controller or a pressure-controlled flow rate controller. The gas supply unit 20 may include at least one flow rate modulation device configured to modulate or pulse the flow rate of the at least one processing gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. As a result, plasma is formed from the at least one processing gas supplied into the plasma processing space 10s. Therefore, the RF power supply 31 may function as at least a portion of the plasma generation unit 12. In addition, by supplying a bias RF signal to the at least one lower electrode, a bias potential is generated in the substrate W, and an ionic component in the formed plasma can be drawn into the substrate W.

In an embodiment, the RF power supply 31 includes a first RF generation unit 31a and a second RF generation unit 31b. The first RF generation unit 31a is coupled to the at least one lower electrode and/or the at least one upper electrode via at least one impedance matching circuit to generate a source RF signal (source RF power) for plasma generation. In an embodiment, the RF signal has a frequency within the range of 10 MHz to 150 MHz. In an embodiment, the first RF generation unit 31a may be configured to generate a plurality of source RF signals having different frequencies. One or more generated source RF signals are supplied to the at least one lower electrode and/or the at least one upper electrode.

The second RF generation unit 31b is coupled to the at least one lower electrode via the at least one impedance matching circuit and is configured to generate a bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency within the range of 100 kHz to 60 MHz. In an embodiment, the second RF generation unit 31a may be configured to generate a plurality of bias RF signals having different frequencies. One or more generated bias RF signals are supplied to the at least one lower electrode. In addition, in various embodiments, at least one of the source RF signal and the bias RF signal may be pulsed.

The power supply 30 may include a DC power supply 32 coupled to the plasma processing chamber 10. The DC power supply 32 includes a first DC generation unit 32a and a second DC generation unit 32b. In an embodiment, the first DC generation unit 32a is connected to the at least one lower electrode and configured to generate a first DC signal. The generated first DC signal is applied to the at least one lower electrode. In an embodiment, the second DC generation unit 32b is connected to the at least one upper electrode and configured to generate a second DC signal. The generated second DC signal is applied to the at least one upper electrode.

In various embodiments, the first and second DC signals may be pulsed. In this case, a sequence of voltage pulses is applied to the at least one lower electrode and/or the at least one upper electrode. The voltage pulse may have a pulse waveform that is rectangular, trapezoidal, triangular, or a combination thereof. In an embodiment, a waveform generation unit configured to generate a sequence of voltage pulses from a DC signal is connected between the first DC generation unit 32a and the at least one lower electrode. Therefore, the first DC generation unit 32a and the waveform generation unit constitute a voltage pulse generation unit. When the second DC generation unit 32b and the waveform generation unit constitute the voltage pulse generation unit, the voltage pulse generation unit is connected to at least one upper electrode. The voltage pulse may have positive polarity or negative polarity. Furthermore, the sequence of voltage pulses may include one or more positive voltage pulses and one or more negative voltage pulses within one period. Furthermore, the first and second DC generation units 32a and 32b may be provided in addition to the RF power supply 31, or the first DC generation unit 32a may be provided in place of the second RF generation unit 31b.

The exhaust system 40 may be connected to, for example, a gas discharge port 10e provided at the bottom of the plasma processing chamber 10. The exhaust system 40 may include a pressure regulating valve and a vacuum pump. The pressure regulating valve regulates the internal pressure of the plasma processing space 10s. The vacuum pump may include a turbo molecular pump, a dry pump, or a combination thereof.

### Example of Etching Method

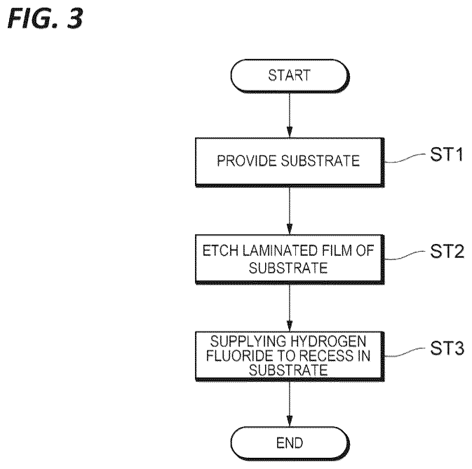

FIG. 3 is a flowchart illustrating an example of an etching method (hereinafter also referred to as “the present method”) according to an embodiment. As illustrated in FIG. 3, the present method includes step ST1 of providing a substrate, step ST2 of etching a film stack of the substrate, and step ST3 of supplying hydrogen fluoride to a recess in the substrate. In an embodiment, the processing in each step may be executed in a plasma processing apparatus 1 (see FIGS. 1 and 2). In the following examples, the control unit 2 controls each component of the capacitively coupled plasma processing apparatus 1 (see FIG. 2) to execute the present method.

### Step ST1: Provision of Substrate

In step ST1, the substrate W is provided in the plasma processing space 10s of the plasma processing apparatus 1. The substrate W is placed in the central region 111a of the substrate support unit 11 and held on the substrate support unit 11 by an electrostatic chuck 1111.

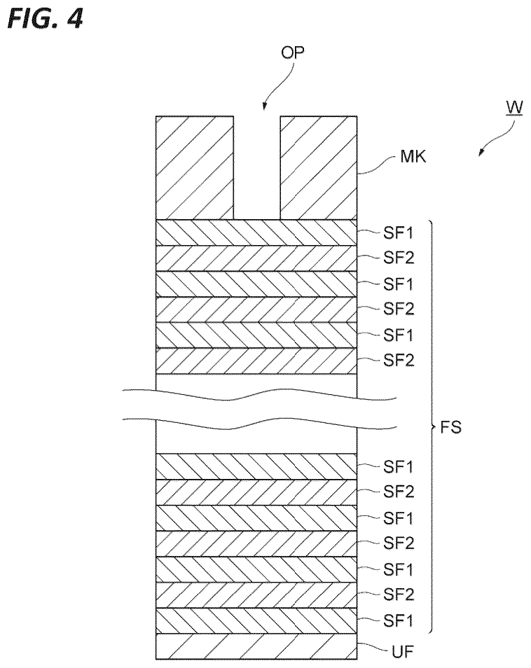

FIG. 4 is a view illustrating an example of the cross-sectional structure of the substrate W supplied in step ST1. As illustrated in FIG. 4, the substrate W has a film stack FS and a mask MK. In an embodiment, the film stack FS and the mask MK are formed on an underlying film UF. That is, the substrate W may be formed by stacking the underlying film UF, the film stack FS, and the mask MK in this order. In an embodiment, the substrate W is used for manufacturing semiconductor devices. Semiconductor devices include semiconductor memory devices such as a 3D-NAND flash memory and a DRAM.

In an embodiment, the underlying film UF is a silicon wafer, or an organic film, a dielectric film, a metal film, a semiconductor film, or the like formed on a silicon wafer. The underlying film UF may be configured by stacking a plurality of films.

The film stack FS is a film to be etched by the present method. The film stack

FS has at least two different silicon-containing films. In an embodiment, the film stack FS has at least two silicon-containing films having different compositions. In an embodiment, the film stack FS may be configured by alternately stacking a silicon oxide film SF1 and a silicon nitride film SF2 a plurality of times, as illustrated in FIG. 4. In an embodiment, the film stack FS may be configured by alternately stacking silicon oxide films and polycrystalline silicon films. In an embodiment, the film stack FS may be configured by stacking a silicon nitride film, a silicon oxide film, and a polycrystalline silicon film in a given order. In an embodiment, the film stack FS may be configured by alternately stacking silicon oxide films and silicon carbonitride films. In an embodiment, the film stack FS may be configured by stacking a silicon oxide film, a silicon nitride film, and a silicon carbonitride film in a given order. A silicon-containing film such as a silicon oxide film, a silicon nitride film, or a polycrystalline silicon film may contain impurities such as phosphorus, boron, or nitrogen.

The mask MK may be formed of a material whose etching rate with respect to the plasma generated in step ST2 is lower than that of the film stack FS. In an embodiment, the mask MK is a carbon-containing film or a metal-containing film. The carbon-containing film is, for example, an amorphous carbon (ACL) film, a spin-on carbon (SOC) film, or a photoresist film. The ACL film may be doped with elements such as boron, arsenic, tungsten, and xenon. In an example, the metal-containing film includes at least one metal selected from the group consisting of tungsten, molybdenum, titanium, ruthenium, samarium, and yttrium. In an example, the metal-containing film may include at least one selected from the group consisting of tungsten carbide (WC), tungsten silicide (WSi), WSiN, and WSiC. The mask MK may be a single layer mask including a single layer film, or may be a multilayer mask including two or more film stacks.

As illustrated in FIG. 4, the mask MK defines at least one opening OP on the film stack FS. The opening OP is a space above the film stack FS and is surrounded by the side wall of the mask MK. That is, the top surface of the film stack FS has a region covered by the mask MK and a region exposed at the bottom of the opening OP.

The opening OP may have any shape when the substrate W is viewed from above, that is, when the substrate W is viewed from the top to the bottom in FIG. 4. The shape may be, for example, a circle, an ellipse, a rectangle, a line, or a combination of one or more of these shapes. The mask MK may have a plurality of side walls, and the plurality of side walls may define a plurality of openings OP. The plurality of openings OP each have a linear shape, and may be aligned at regular intervals to form a line-and-space pattern. In addition, the plurality of openings OP may each have a hole shape and form an array pattern.

Individual films (the underlying film UF, the film stack FS, and the mask MK) constituting the substrate may be formed by a CVD method, an ALD method, a PVD method, a spin coating method, or the like. The mask MK may be formed by lithography. In addition, the opening OP of the mask MK may be formed by etching the mask MK. Each film may be a flat film or an uneven film. In an embodiment, the substrate W may further include another film under the underlying film UF. In this case, a recess having a shape corresponding to the opening OP may be formed in the film stack FS and the underlying film UF, and may be used as a mask for etching the another film.

In an embodiment, at least a part of the process of forming each film of the substrate W may be performed within a plasma processing space 10s as a part of the step ST1. For example, when forming the opening OP of the mask MK by etching, the etching in step ST1 and the etching of the film stack FS in step ST2 may be performed continuously within the plasma processing space 10s. In an embodiment, the substrate W may be provided within the plasma processing space 10s after all or a part of each film on the substrate W is formed in an apparatus or chamber outside the plasma processing apparatus 1.

In an embodiment, after the substrate W is provided to the central region 111a of the substrate support unit 11, the substrate support unit 11 is controlled to a predetermined temperature by a temperature regulating module. In an example, controlling the temperature of the substrate support unit 11 to a given temperature includes setting the temperature of the heat transfer fluid flowing through the flow path 1110a or the heater temperature to the given temperature, or setting the temperature to a temperature different from the given temperature. The timing at which the heat transfer fluid starts flowing into the flow path 1110a may be before or after the substrate W is placed on the substrate support unit 11, or may be at the same time. In addition, the temperature of the substrate support unit 11 may be controlled to the given temperature before step ST1. That is, the substrate W may be provided to the substrate support unit 11 after the temperature of the substrate support unit 11 is controlled to a given temperature. In an embodiment, the given temperature is 0° C. or lower, −10° C. or lower, −20° C. or lower, or −30° C. or lower. In an embodiment, the given temperature is −70° C. or higher, −60° C. or higher, −50° C. or −40° C., or higher.

In an embodiment, instead of controlling the substrate support unit 11 to the given temperature, the substrate W may be controlled to the given temperature. Controlling the temperature of the substrate W to the given temperature includes setting the temperature of the substrate support unit 11, the heat transfer fluid flowing through the flow path 1110a, and/or the temperature of a heater to the given temperature, or setting the temperature to a temperature different from the given temperature.

### Step ST2: Etching of Film Stack FS

In step ST2, the film stack FS of the substrate W is etched. As a result, a portion of the film stack FS that is not covered by the mask MK (the portion exposed in the opening OP) is etched, and a recess portion is formed.

### Supply of First Processing Gas

First, the first processing gas is supplied from the gas supply unit 20 into the plasma processing space 10s. The first processing gas contains hydrogen fluoride (HF) gas. In an embodiment, the HF gas may have the highest flow rate (partial pressure) other than the inert gas in the first processing gas. In an example, with respect to the total flow rate of the first processing gas (when the first processing gas contains an inert gas, the flow rate of all gases except the inert gas), the flow rate of the HF gas may be 50 vol % or more, 60 vol % or more, 70 vol % or more, 80 vol % or more, 90 vol % or more, or 95 vol % or more. The flow rate of the HF gas may be less than 100 vol %, 99.5 vol % or less, 98 vol % or less, or 96 vol % or less with respect to the total flow rate of the first processing gas. In an example, the flow rate of the HF gas is 70 vol % or more and 96 vol % or less with respect to the total flow rate of the first processing gas.

In an embodiment, the first processing gas may contain a phosphorus-containing gas. The phosphorus-containing gas is a gas containing phosphorus-containing molecules. The phosphorus-containing molecules may be an oxide such as tetraphosphorus decaoxide (_{P}O₁₀), tetraphosphorus octoxide (P₄O₈), or tetraphosphorus hexaoxide (P₄O₆). Tetraphosphorus decaoxide is sometimes called diphosphorus pentoxide (P₂O₅)). The phosphorus-containing molecules may be a halide (phosphorus halide) such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), or phosphorus iodide (PI₃). That is, the phosphorus-containing molecules may contain fluorine as a halogen element, such as phosphorus fluoride. Alternatively, the phosphorus-containing molecules may contain a halogen element other than fluorine as the halogen element. The phosphorus-containing molecules may be a phosphoryl halide, such as phosphoryl fluoride (POF₃), phosphoryl chloride (POCl₃), or phosphoryl bromide (POBr₃). The phosphorus-containing molecules may be phosphine (PH₃), calcium phosphide (such as Ca₃P₂), phosphoric acid (H₃PO₄), sodium phosphate (Na₃PO₃), hexafluorophosphate (HPF₆), or the like. The phosphorus-containing molecules may be fluorophosphines (H_{g}PFₕ). Here, the sum of g and h is 3 or 5. Examples of fluorophosphines include HPF₂ and H₂PF₃. The first processing gas may contain one or more of the above-mentioned phosphorus-containing molecules as at least one phosphorus-containing molecule. For example, the first processing gas may include at least one of PF₃, PCl₃, PF₅, PCl₅s, POCl₃, PH₃, PBr₃, or PBr₅ as the at least one phosphorus-containing molecule. When each phosphorus-containing molecule contained in the first processing gas is liquid or solid, each phosphorus-containing molecule may be vaporized by heating or the like and then supplied into the plasma processing space 10s.

In an example, the phosphorus-containing gas may be PClₐF_{b} (a is an integer of 1 or more, b is an integer of 0 or more, and a+b is an integer of 5 or less) gas or PC_{c}H_{d}F_{c} (d and e are each an integer of 1 or more and 5 or less, and c is an integer of 0 or more and 9 or less) gas.

The PClₐF_{b} gas may be, for example, at least one gas selected from the group consisting of PCIF₂ gas, PCl₂F gas, and PCl₂F₃ gas.

The PC_{c}H_{d}Fₑ gas may be, for example, at least one selected from the group consisting of PF₂CH₃ gas, PF(CH₃)₂ gas, PH₂CF₃gas, PH(CF₃)₂ gas, PCH₃(CF₃)₂ gas, PH₂F gas, and PF₃(CH₃)₂ gas. One type of gas is sufficient.

In an example, the phosphorus-containing gas may be PCl_{c}F_{d}CₑH_{f} (c, d, e, and f are each an integer of 1 or more) gas. In addition, the phosphorus-containing gas may be a gas containing phosphorus (P), fluorine (F), and halogens other than F (fluorine) (e.g., Cl, Br, or I) in its molecular structure, a gas containing phosphorus (P), fluorine (F), carbon (C), and hydrogen (H) in its molecular structure, or a gas containing phosphorus (P), fluorine (F), and hydrogen (H) in its molecular structure.

In an example, a phosphine-based gas may be used as the phosphorus-containing gas. Examples of the phosphine gas include phosphine (PH₃), a compound in which at least one hydrogen atom of phosphine is substituted with an appropriate substituent, and a phosphine acid derivative.

Substituents that replace the hydrogen atoms of phosphine are not particularly limited, and include, for example, halogen atoms such as fluorine atoms and chlorine atoms; alkyl groups such as methyl, ethyl, and propyl groups; and hydroxyalkyl groups such as hydroxymethyl, hydroxyethyl groups, and hydroxypropyl groups, and examples include chlorine atoms, methyl groups, and hydroxymethyl groups.

Examples of the phosphinic acid derivative include phosphinic acid (H₃O₂P), alkylphosphinic acid (PHO(OH)R), and dialkylphosphinic acid (PO(OH)R₂).

As the phosphine gas, at least one gas selected from, for example, the group consisting PCH₃Cl₂(dichloro(methyl)phosphine) gas, P(CH₃)₂Cl (chloro(dimethyl)phosphine) gas, P(HOCH₂)Cl₂ (dichloro(hydroxylmethyl)phosphine) gas, P(HOCH₂)₂Cl (chloro(dihydroxylmethyl)phosphine) gas, P(HOCH₂)(CH₃)₂(dimethyl(hydroxylmethyl)phosphine) gas, HOCH₂)₂(CH₃)(methyl(dihydroxylmethyl)phosphine) gas, P(HOCH₂)₃ (tris(hydroxylmethyl)phosphine) gas, H₃O₂P (phosphinic acid) gas, PHO(OH)(CH₃)(methylphosphinic acid) gas and PO(OH)(CH₃)₂ (dimethylphosphinic acid) gas may be used.

In an embodiment, the flow rate of the phosphorus-containing gas contained in the first processing gas is 20 vol % or less, 10 vol % or less, or 5 vol % or less of the total flow rate of the first processing gas.

In an embodiment, the first processing gas may contain a tungsten-containing gas. The tungsten-containing gas may be a gas containing tungsten and halogen, and an example is WFₓCl_{y} gas (x and y are each an integer of 0 or more and 6 or less, and the sum of x and y is 2 or more and 6or less). Specifically, tungsten-containing gas may be a gas containing tungsten and fluorine, such as tungsten difluoride (WF₂) gas, tungsten tetrafluoride (WF₄) gas, tungsten pentafluoride (WF₅) gas, or tungsten hexafluoride (WF₆) gas, or a gas containing tungsten and chlorine, such as tungsten dichloride (WCl₂) gas, tungsten tetrachloride (WCl₄) gas, tungsten pentachloride (WCl₅ gas, or tungsten hexachloride (WCl₆) gas. Among these, at least one of WF₆ gas and WCl₆ gas may be used. The flow rate of the tungsten-containing gas may be 5 vol % or less of the total flow rate of the first processing gas. In an embodiment, the first processing gas may contain at least one of a titanium-containing gas, a molybdenum-containing gas, and a ruthenium-containing gas instead of or in addition to the tungsten-containing gas.

In an embodiment, the first processing gas may contain a carbon-containing gas. The carbon-containing gas may be, for example, either or both of a fluorocarbon gas and a hydrofluorocarbon gas. In an example, the fluorocarbon gas may be at least one selected from the group consisting of CF₄ gas, C₂F₂ gas, C₂F₄ gas, C₃F₆ gas, C₃F₈ gas, C₄F₆ gas, C₄F₈ gas, and C₅F₈ gas. In an example, the hydrofluorocarbon gas may be at least one selected from the group consisting of CHF₃ gas, C₂F₂ gas, C₃F gas, C₂HF₅ gas, C₂H₂F₄ gas, C₂H₃F₃ gas, C₂H₄F₂ gas, C₃HF₇ gas, C₃H₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₈ gas, C₅H₂F₁₀ gas, and C₅H₃F₇ gas. In addition, the carbon-containing gas may be a linear gas having an unsaturated bond. Examples of the linear carbon-containing gas having an unsaturated bond may be at least one selected from the group consisting of hexafluoropropene (C₃F₆) gas, octafluoro-1-butene, octafluoro-2-butene (C₄F₈) gas, 1,3,3,3-tetrafluoropropene (C₃H₂F₄gas, trans-1,1,1,4,4,4-hexafluoro-2-butene (C₄H₂F₆) gas, pentafluoroethyl trifluorovinyl ether (C₄F₈O) gas, 1,2,2,2-tetrafluoroethne-1-one (CF₃COF) gas, difluoroacetic acid fluoride (CHF₂COF) gas, and carbonyl fluoride (COF₂) gas. In addition, the carbon-containing gas may contain a halogen other than fluorine, may contain fluorine and a halogen other than fluorine, and may contain two or more types of halogens other than fluorine. In an example, the carbon-containing gas may be CₛHₜBrᵤClᵥF_{w} (where s is an integer of 1 or more, and t, u, v, and w are each an integer of 0 or more), or may be CₛHₜBrᵤClᵥF_{w} (where s is an integer of 1 or more and 16 or less, and t, u, v, and w are each 0 or more and 16 or less and satisfy 4≤t+u+v+w≤16). For example, the carbon-containing gas may include at least one selected from the group consisting of CCl₄, CH₂Cl₂, CHCl₃, CF₂Cl₂, CH₂CIF, CHCl₂F, CBr₂F₂, C₂F₅Br, CF₃I, C₂F₅I, and C₃F₇I.

In an embodiment, the first processing gas may contain an oxygen-containing gas. The oxygen-containing gas may be, for example, at least one gas selected from the group consisting of O₂, CO, CO₂, H₂O, and H₂O₂. In an example, the oxygen-containing gas may be an oxygen-containing gas other than H₂O, such as at least one gas selected from the group consisting of O₂, CO, CO₂, and H₂O₂. The flow rate of the oxygen-containing gas may be regulated depending on the flow rate of other gases (e.g., a carbon-containing gas) contained in the first processing gas.

In an embodiment, the first processing gas may contain a halogen-containing gas other than fluorine. The halogen-containing gas other than fluorine may be a chlorine-containing gas, a bromine-containing gas, and/or an iodine-containing gas. In an example, the chlorine-containing gas may be at least one gas selected from the group consisting of Cl₂, HCl, SiCl₂, SiCl₄, CCl₄, SiH₂Cl₂, Si₂Cl₆, CHCl₃, SO₂Cl₂, BCl₃, PCl₃, PCl₅, and POCl₃. In an example, the bromine-containing gas may be at least one gas selected from the group consisting of Br₂, HBr, CBr₂F₂, C₂F₅Br, PBr₃, PBr₅, POBr₃, and BBr₃. In an example, the iodine-containing gas may be at least one gas selected from the group consisting of HI, CF₃I, C₂F₅I, C₃F₇I, IF₅, IF₇, I₂, and PI3. In an example, the halogen-containing gas other than fluorine may be at least one selected from the group consisting of Cl₂ gas, Br₂ gas, and HBr gas. In an example, the halogen-containing gas other than fluorine is Cl₂ gas or HBr gas.

In an embodiment, the first processing gas may further contain an inert gas. In an example, the inert gas may be a noble gas such as Ar gas, He gas, Kr gas, or nitrogen gas.

In an embodiment, the first processing gas may contain a gas capable of generating hydrogen fluoride species (HF species) in the plasma instead of a part or all of the HF gas. The HF species includes at least one of hydrogen fluoride gas, radicals, and ions.

The gas capable of generating HF species may be, for example, a hydrofluorocarbon gas. The hydrofluorocarbon gas may have 2 or more carbon atoms, 3 or more carbon atoms, or 4 or more carbon atoms. In an example, the hydrofluorocarbon gas is at least one selected from the group consisting of CH₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ as, C₅H₂F₁₀ gas, and C₅H₃F₇ gas. In an example, the hydrofluorocarbon gas is at least one selected from the group consisting of CH₂F₂ gas, C₃H₂F₄ gas, C₃H₂F₆ gas, and C₂H₂F₆ gas.

The gas capable of generating HF species may be, for example, a ed gas containing a hydrogen source and a fluorine source. The hydrogen source may be, for example, at least one selected from the group consisting of H₂ gas, NH₃ gas, H₂O gas, H₂O₂ gas, and a hydrocarbon gas (e.g., CH₄ gas or C₃H₆ gas). The fluorine source may be a carbon-free fluorine-containing gas, such as NF₃ gas, SF₆ gas, WF₆ gas, or XeF₂ gas. The fluorine source may also be a fluorine-containing gas containing carbon, such as a fluorocarbon gas and a hydrofluorocarbon gas. In an example, the fluorocarbon gas may be at least one selected from the group consisting of CF₄ gas, C₂F₂ gas, C₂F₄ gas, C₃F₆ gas, C₃F₈ gas, C₄F₆ gas, C₄F₂ gas, and C₅F₈ gas. In an example, the hydrofluorocarbon gas is at least one selected from the group consisting of CHF₃ gas, CH₂F₂ gas, CH₃F gas, C₂HF₅ gas, and a hydrofluorocarbon gas containing three or more C (e.g., C₃H₂F₄ gas, C₃H₂F₆ gas, or C₄H₂F₆ gas).

### Generation of Plasma

Next, a source RF signal is supplied to the lower electrode of the substrate support unit 11 and/or the upper electrode of the shower head 13. As a result, a high-frequency electric field is generated between the shower head 13 and the substrate support unit 11, and plasma is generated from the first processing gas in the plasma processing space 10s. A bias signal may be supplied to the lower electrode of the substrate support unit 11. In this case, a bias potential is generated between the plasma and the substrate W. Active species such as ions and radicals in the plasma are attracted to the substrate W by the bias potential. The bias signal may be a bias RF signal supplied from the second RF generation unit 31b. In addition, the bias signal may be a bias DC signal supplied from the DC generation unit 32a.

In an embodiment, the source RF signal and the bias signal may both be continuous waves or pulse waves, or one may be a continuous wave and the other pulse wave. When both the source RF signal and the bias signal are pulse waves, the periods of both pulse waves may or may not be synchronized. The duty ratio of the source RF signal and/or bias signal pulse wave may be set as appropriate, for example, from 1 to 80%, or from 5 to 50%. In addition, when a bias DC signal is used as the bias signal, the pulse wave may have a waveform of a rectangle, a trapezoid, a triangle, or a combination thereof. The polarity of the bias DC signal may be negative or positive as long as the potential of the substrate W is set to provide a potential difference between the plasma and the substrate and draw in ions.

In an embodiment, supply and cutoff of at least one of the source RF signal and the bias signal may be alternately repeated. For example, supply and cutoff of the bias signal may be alternately repeated while the source RF signal is continuously supplied. In addition, for example, the bias signal may be continuously supplied while supply and cutoff of the source RF signal are alternately repeated. Furthermore, for example, supply and cutoff of both the source RF signal and the bias signal may be alternately repeated.

In an embodiment, the composition of the first processing gas and the flow rate (partial pressure) of each gas may be constant during the processing in step ST2. In an embodiment, the configuration of the first processing gas and/or the flow rate (partial pressure) of each gas may be changed as the etching progresses in step ST2.

In an embodiment, during the processing in step ST2, the temperature of the substrate support unit 11 may be controlled to the given temperature set in step ST1. In an embodiment, instead of the temperature of the substrate support unit 11, the temperature of the substrate W may be controlled to the given temperature.

In an embodiment, during the processing in step ST2, the pressure within the plasma processing chamber 10 may be controlled to 1 mTorr or higher and 50 mTorr or lower.

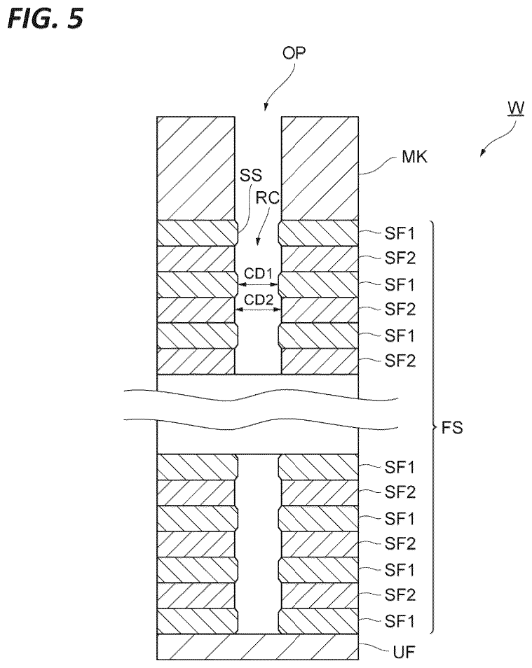

FIG. 5 is a view illustrating an example of the cross-sectional structure of the substrate W after the processing in step ST2. By the etching in step ST2, a portion of the film stack FS that is not covered by the mask MK (the portion exposed in the opening OP) is etched to form a recess RC. Here, the opening dimensions in the recess RC formed in the film stack FS may become non-uniform along the depth direction. For example, the opening dimensions of the recess RC may vary depending on the types of films forming the film stack FS. The reason for this is not necessarily clear, but for example, it may be conceivable that the etching rate in the horizontal direction differs for each film because the reactivity to active species in the plasma and the types and amounts of byproducts deposited on the side wall differ for each film.

In the example illustrated in FIG. 5, the opening dimensions in the recess RC formed in the film stack FS are different between a silicon oxide film SF1 and a silicon nitride film SF2. In an embodiment, the opening dimension CD1 in the silicon oxide film SF1 is smaller than the opening dimension CD2 in the silicon nitride film SF2. The recess RC has opening dimensions CD1 and opening dimensions CD2 alternately along the depth direction. As a result, the side wall SS of the film stack FS defining the recess RC has unevenness along the depth direction. In an example, the side wall SS in the film stack FS may have a shell-like uneven shape along the depth direction. Such unevenness is sometimes called a scallop due to its shape. Scallop is one of the shape abnormalities caused by etching. In an embodiment, the surface roughness of the side wall SS (the difference between the opening dimension CD1 and the opening dimension CD2) is 0.2 nm or more.

In the present method, it is possible to improve the surface roughness of the side wall SS in the film stack FS (the uniformity in the opening size of the recess RC in the depth direction) by step ST3 described below.

### Step ST3: Supply of Hydrogen Fluoride to Recess

In step ST3, hydrogen fluoride is supplied to the recess RC in the film stack FS. In an embodiment, hydrogen fluoride may be provided as HF gas. In an embodiment, step ST3 may be executed continuously from step ST2 in the same chamber as step ST2. Specifically, the second processing gas containing HF gas is supplied from the gas supply unit 20 into the plasma processing space 10s. In an embodiment, the second processing gas may include an inert gas as described above. By supplying hydrogen fluoride gas to the recess RC formed in the film stack FS of the substrate W, the side wall SS in the film stack FS is etched in the horizontal direction. The etching rate for HF gas may vary depending on each film forming the side wall SS. That is, the etching amount for the side wall SS etched in step ST3 may vary from film to film.

In an embodiment, the HF gas may have the highest flow rate (partial pressure) other than the inert gas in the second processing gas. In an example, with respect to the total flow rate of the first processing gas (when the second processing gas contains an inert gas, the flow rate of all gases except the inert gas), the flow rate of the HF gas may be 50 vol % or more, 60 vol % or more, 70 vol % or more, 80 vol % or more, 90 vol % or more, or 95 vol % or more. The flow rate of the HF gas may be less than 100 vol %, 99.5 vol % or less, 98 vol % or less, or 96 vol % or less with respect to the total flow rate of the second processing gas. In an example, the flow rate of the HF gas is 70 vol % or more and 96 vol % or less with respect to the total flow rate of the first processing gas.

In an embodiment, the second processing gas may contain the above-mentioned phosphorus-containing gas. In an embodiment, the flow rate of the phosphorus-containing gas contained in the second processing gas is 20 vol % or less, 10 vol % or less, or 5 vol % or less of the total flow rate of the second processing gas.

In an embodiment, during the processing in step ST3, the temperature of the substrate support unit 11 may be controlled to a temperature lower than or higher than the given temperature set in step ST1 and/or step ST2. In an example, the temperature of the substrate support unit 11 is 0° C. or lower, −10° C. or lower, −20° C. or −30° C., −40° C., or −50° C. or lower. In an embodiment, the given temperature is −70° C. or higher or −60° C. or higher. In an embodiment, instead of the temperature of the substrate support unit 11, the temperature of the substrate W may be controlled to the above-mentioned temperature lower than the given temperature. This may make it possible to improve the etching rate of the silicon oxide film by HF gas.

In an embodiment, the pressure in the plasma processing chamber 10 during the processing in step ST3 is higher than the pressure in the plasma processing chamber 10 in step ST2.

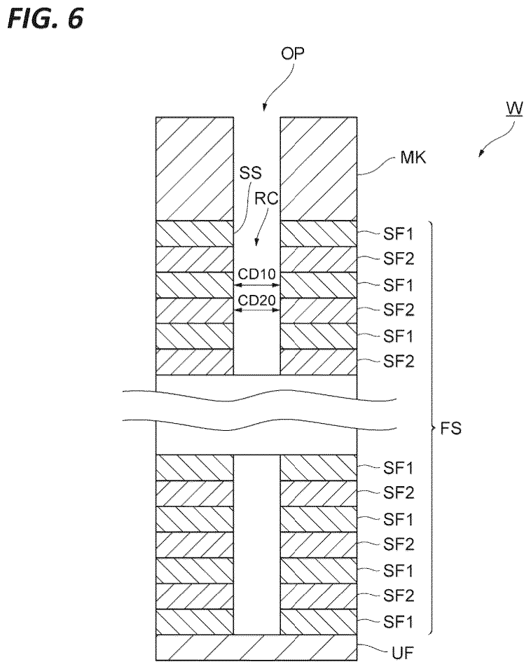

FIG. 6 is a view illustrating an example of the cross-sectional structure of the substrate W after the processing in step ST3. As illustrated in FIG. 6, in step ST3, the opening dimension CD10 of a silicon oxide film SF1 and the opening dimension CD20 of a silicon nitride film SF2 in the recess RC may become substantially the same. In an embodiment, the surface roughness of the side wall SS (the difference between the opening dimension CD10 and the opening dimension CD20) is less than 1 nm. That is, the surface roughness of the side wall SS can be improved.

The reason for this is thought to be that on the side wall SS of the film stack FS, etching of the silicon oxide film SF1 progresses in the horizontal direction, while etching of the silicon nitride film SF2 is suppressed. In an example, the etching selectivity ratio of the silicon oxide film SF1 to the silicon nitride film SF2 (the etching rate of the silicon oxide film SF1 by the second processing gas/the etching rate of the silicon nitride film SF2 by the second processing gas) is 10 or more, 15 or more, 20 or more, or 25 or more.

According to the present method, it is possible to suppress an abnormal shape such a scallop in a recess formed in a film stack by etching so that the surface roughness of the side wall in the film stack can be improved.

### Modifications

Modifications of the present method will be described. The present disclosure is not limited in any way by the following modifications.

In an embodiment, step ST3 may include the following two steps ST31 and ST32. Step ST31 is a step of controlling the temperature of the substrate support unit 11 to a first temperature and controlling the partial pressure of the hydrogen fluoride gas in the chamber to a first pressure. Step ST32 is executed after step ST31 to control the temperature of the substrate support unit 11 to a second temperature and control the partial pressure of the hydrogen fluoride gas in the chamber to the second pressure. In an embodiment, in step ST31 and step ST32, the temperature of the substrate W may be controlled instead of controlling the temperature of the substrate support unit 11.

In an embodiment, the second temperature may be higher than the first temperature. In an embodiment, the second pressure may be lower than the first pressure.

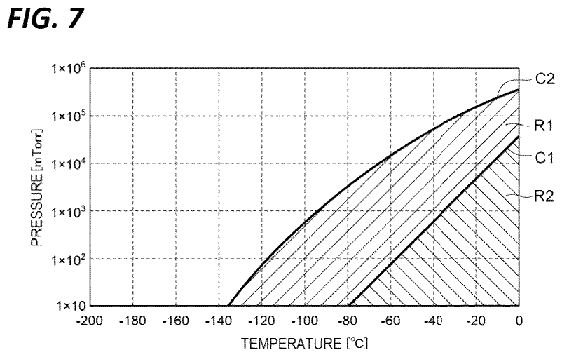

FIG. 7 is a graph showing an example of an adsorption equilibrium pressure curve of hydrogen fluoride. The horizontal axis represents temperature (° C.). The vertical axis represents pressure (mTorr). C1 is the adsorption equilibrium pressure curve of hydrogen fluoride. C2 is the saturated vapor pressure curve of hydrogen fluoride. At the temperature and pressure on the adsorption equilibrium pressure curve C1 in the graph of FIG. 7, adsorption and desorption of hydrogen fluoride are in equilibrium. In an embodiment, the adsorption equilibrium pressure curve C1 may be drawn by an exponential function approximated using measured data based on the BET adsorption theory.

In an embodiment, the first temperature and the first pressure are located in a first region above the hydrogen fluoride adsorption equilibrium pressure curve C1 of the graph shown in FIG. 7. As a result, in step ST31, the hydrogen fluoride is adsorbed on the surface of the side wall SS in the film stack FS, and volatile by-products are formed. The first region may be located in a region below the saturated vapor pressure curve C2 of hydrogen fluoride (the region indicated by “R1” in the graph of FIG. 7). In this case, the hydrogen fluoride is adsorbed in a vapor phase on the surface of the side wall SS in the film stack FS. The first region may be located above the saturated vapor pressure curve C2. In this case, the hydrogen fluoride is adsorbed in a liquid phase on the surface of the side wall SS in the film stack FS. In an embodiment, the adsorbed amount of hydrogen fluoride and the formed amount of byproducts on the side wall SS in the silicon oxide film SF1 are larger than those on the side wall SS in the silicon nitride film SF2.

In an embodiment, the second temperature and the second pressure are in a second region below the adsorption equilibrium pressure curve C1 of hydrogen fluoride in the graph shown in FIG. 7 (the region indicated by “R2” in the graph of FIG. 7). As a result, in step ST32, the hydrogen fluoride and byproducts adsorbed on the surface of the side wall SS in the film stack FS are desorbed. In an embodiment, the desorbed amounts of hydrogen fluoride and byproducts from the side wall SS in the silicon oxide film SF1 are larger than those from the side wall SS in the silicon nitride film SF2. As a result, the horizontal etching of the silicon oxide film SF1 progresses more than that of the silicon nitride film SF2.

In an embodiment, in step ST3, a cycle including step ST31 and step ST32 may be executed multiple times.

In an embodiment, step ST3 may be executed in a different chamber (hereinafter, referred to as a “second chamber”) from step ST2. For example, step ST3 may include a step of transferring the substrate W from the plasma processing chamber 10 to a second chamber, and a step of supplying the above-described second processing gas to the substrate W in the second chamber. In an embodiment, the second chamber may be a portion of the substrate processing system PSI described below. In an embodiment, the second chamber may be a portion of a separate substrate processing apparatus outside the plasma processing system including the plasma processing apparatus 1.

In an embodiment, the conditions of step ST3 may be set based on data indicating the shape of the recess RC in the film stack FS. The surface roughness of the side wall SS after step ST2 may vary depending on the depth of the recess RC. In such a case, it may be possible to improve the surface roughness of the side wall SS by setting the conditions of step ST3 based on the data showing the shape of the recess RC in the film stack FS, regardless of the depth of the recess RC.

The data showing the shape of the recess portion RC in the film stack FS may be obtained by observing a substrate W after step ST2 using a sensor. The sensor may be an optical sensor or other sensor. The sensor may be configured to be able to observe a substrate W placed on the substrate support unit 11 in the plasma processing chamber 10, or may be configured to be able to observe a substrate W outside the plasma processing chamber 10. In an example, the sensor is installed within a transfer module TM, which will be described below. The data showing the shape of the recessed portion RC in the film stack FS may be data estimated from the plasma emission state in step ST2 and/or the change in mass of the substrate W before and after step ST2, or may be data estimated, for example, by simulation.

In an embodiment, the conditions set based on data showing the shape of the recess RC in the film stack FS include the pressure of the plasma processing chamber 10 in which the substrate W is accommodated (hereinafter, also referred to as “pressure”), the temperature of the substrate W or the substrate support unit 11 that supports the substrate W (hereinafter, also referred to as “temperature”), and the flow rate of hydrogen fluoride gas (hereinafter, also referred to as “flow rate”).

In an embodiment, the pressure, the temperature, and the flow rate may be set as follows based on data showing the shape of the recess RC. Here, the pressure, the temperature, and the flow rate when the surface roughness of the side wall SS is uniform or substantially uniform in the depth direction of the recess RC are defined as reference values. When the surface roughness of the side wall SS becomes smaller from the upper side (opening side) to the lower side (bottom side) of the recess RC, the pressure and the flow rate may be set to be lower than the standard values, and the temperature may be set to be higher than the standard value. In addition, when the surface roughness of the side wall SS increases from the upper side to the lower side of the recess RC, the pressure and the flow rate may be set to be higher than the reference values, and the temperature may be set to be lower than the reference value. In addition, when the surface roughness of the middle portion of the recess RC is the smallest and the surface roughness of the upper and lower sides of the recess RC are about the same, only the temperature may be set to be lower than the reference value while keeping the pressure and the flow rate at their reference values. In addition, when the surface roughness of the middle part of the recess RC is the smallest and the surface roughness of the lower portion of the recess RC is larger than the upper portion of the recess RC, the pressure and the flow rate may be set to be higher than the reference values while keeping the temperature at the reference value. In addition, when the surface roughness of the middle part of the recess RC is the smallest and the surface roughness of the upper portion of the recess RC is larger than the lower portion of the recess RC, the pressure and the flow rate may be set to be lower than the reference values while keeping the temperature at the reference value.

In an embodiment, during the execution of step ST3, the conditions of step ST3 may be changed depending on the depth of the recess RC. For example, step 3 may include the following two steps ST33 and ST34. Step ST33 is a step of supplying the hydrogen fluoride to the recess RC in the film stack FS under first conditions. Step 34 is a step of supplying the hydrogen fluoride to the recess RC in the film stack FS under second conditions different from the first conditions. In step 3, a cycle including steps 33 and 34 may be performed multiple times.

In an embodiment, the second conditions may be different from the first conditions in at least one selected from the group consisting of the pressure of the plasma processing chamber 10 in which the substrate W is accommodated, the temperature of the substrate W or the substrate support unit 11 that supports the substrate W, and the flow rate of the hydrogen fluoride gas.

In an embodiment, the present method may be executed using a substrate processing system PS1 that includes multiple substrate processing chambers.

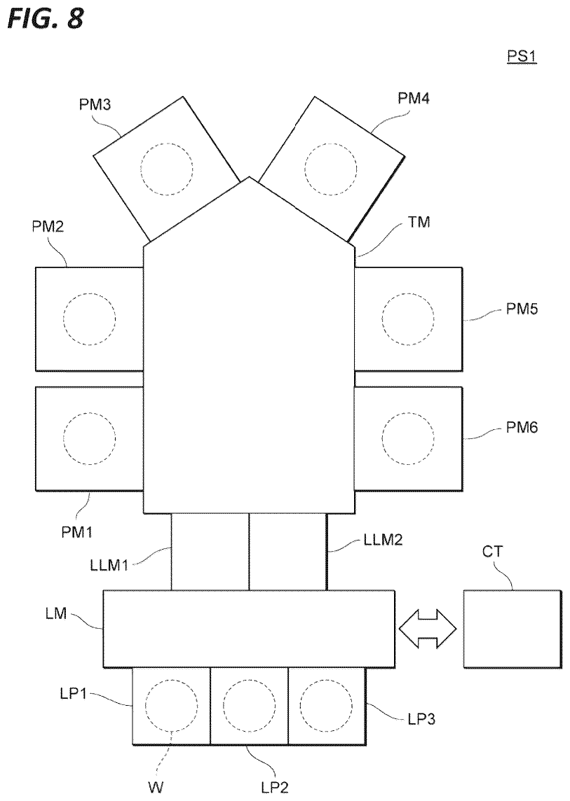

FIG. 8 is a view illustrating a configuration example of a substrate processing system PS1. The substrate processing system PS1 includes substrate processing chambers PM1 to PM6 (hereinafter, also collectively referred to as “substrate processing modules PM”), a transfer module TM, and load-lock modules LLM1 and LLM2 (hereinafter, also collectively referred to as “load-lock modules LLM”), a loader module LM, and load ports LP1 to LP3 (hereinafter, also collectively referred to as “load ports LP”). A control unit CT controls each component of the substrate processing system PS1 to execute a given processing on a substrate W.

The substrate processing modules PM perform therein processings, such as an etching processing, a trimming processing, a film forming processing, an annealing processing, a doping processing, a lithography processing, a cleaning processing, and an ashing processing, respectively, on a substrate W. At least one of the substrate processing chambers PM1 to PM6 may be the plasma processing apparatus 1 illustrated in FIG. 1 or FIG. 2.

The transfer module TM has a transfer apparatus configured to transfer substrates W, and transfers substrates W between the substrate processing modules PM or between the substrate processing modules PM and the load-lock modules LLM. The substrate processing modules PM and the load-lock modules LLM are arranged adjacent to the transfer module TM. The transfer module TM, the substrate processing modules PM, and the load-lock modules LLM are spatially isolated or connected by gate valves that can be opened and closed.

The load-lock modules LLMI and LLM2 are provided between the transfer module TM and the loader module LM. The load-lock modules LLM may switch the internal pressures thereof to atmospheric pressure or vacuum. The “atmospheric pressure” may be the pressure outside each module included in the substrate processing system PS1. In addition, the “vacuum” is a pressure lower than the atmospheric pressure, and may be a medium vacuum of, for example, 0.1 Pa to 100 Pa. The load-lock modules LLM transfer substrates W from the loader module LM under atmospheric pressure to the transfer module TM under vacuum, and also transfer the substrates W from the transfer module TM under vacuum to the loader module LM under atmospheric pressure.

The loader module LM has a transfer apparatus that transfers substrates W, and transfers the substrates W between the load-lock modules LLM and the load ports LP. A front opening unified pod (FOUP) capable of accommodating, for example, 25 substrates W, or an empty FOUP may be placed in each of the load ports LP. The loader module LM takes out the substrates W from the FOUPs in the load ports LP and transfer the substrates to the load-lock modules LLM. In addition, the loader module LM takes out the substrates W from the load-lock modules LLM and transfers the substrates to the FOUPs in the load ports LP.

The control unit CT controls each component of the substrate processing system PS1 to execute given processings on the substrates W. The control unit CT stores a recipe in which, for example, process procedures, process conditions, and transfer conditions are set, and controls each component of the substrate processing system PS to perform predetermined processings on the substrates W according to the recipe. The control unit CT may also execute some or all of the functions of the control unit 2 illustrated in FIGS. 1 and 2. The present method may be executed in the substrate processing system PS1 under the control of the control unit CT. In an embodiment, steps ST1 to ST3 may be executed in one of the substrate processing chambers PM1 to PM6. In addition, for example, step STI and step ST2 may be executed in one of the substrate processing chambers PM1 to PM6, and step ST3 may be executed in another one of the substrate processing chambers PM1 to PM6.

In an embodiment, in step ST3, a processing liquid containing hydrogen fluoride may be supplied to the substrate. For example, step ST3 may include a step of transferring the substrate W to a liquid processing apparatus outside the plasma processing chamber 10, and a step of supplying a processing liquid containing hydrogen fluoride to the substrate W in the liquid processing apparatus. The processing liquid may be, for example, hydrofluoric acid (DHF) or buffered hydrofluoric acid (BHF). In an embodiment, the liquid processing apparatus may be a portion of a substrate processing system PS2 described below.

In an embodiment, the present method may be executed using a substrate processing system PS2 that includes a liquid processing apparatus.

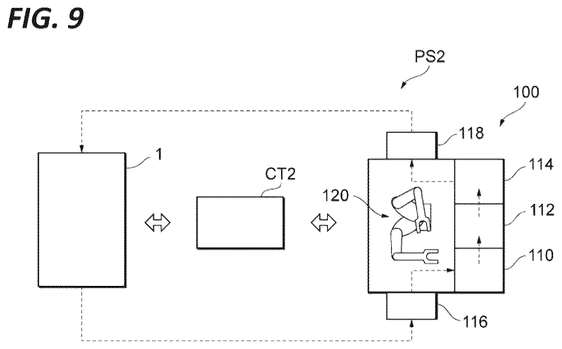

FIG. 9 is a view illustrating a configuration example of the substrate processing system PS2. In an embodiment, the substrate processing system PS2 includes a plasma processing apparatus 1 (see FIGS. 1 and 2), a liquid processing apparatus 100, and a control unit CT2. The substrate processing system PS2 may include a transfer apparatus that transfers a substrate W between the plasma processing apparatus 1 and the liquid processing apparatus 100.

In an embodiment, the liquid processing apparatus 100 includes a container 110 configured to contain a processing liquid containing hydrogen fluoride, a container 112 configured to contain a rinsing liquid, and a container 114 configured to contain pure water. In an embodiment, the liquid processing apparatus 100 may include a dryer configured to dry a substrate W.

In an embodiment, the liquid processing apparatus 100 includes a loading port 116 configured to receive a substrate W loaded out from the plasma processing apparatus 1 and an unloading port 118 configured to unload a substrate W to the plasma processing apparatus 1. In an embodiment, the liquid processing apparatus 100 includes a transfer apparatus 120 configured to transfer a substrate W. The transfer apparatus 120 transfers a substrate W from the loading port 116 to the container 110. The transfer apparatus 120 transfers a substrate W from the container 110 to the container 112. The transfer apparatus 120 transfers a substrate W from the container 112 to the container 114. The transfer apparatus 120 transfers a substrate W from the container 114 to the unloading port 118.

The control unit CT2 is configured to control each component of the plasma processing apparatus 1 and the liquid processing apparatus 100. The control unit CT2 may also execute some or all of the functions of the control unit 2 illustrated in FIGS. 1 and 2. The present method may be executed in the substrate processing system PS2 under the control of the control unit CT2.

In an embodiment, step ST and step ST2 are executed in the plasma processing apparatus 1 of substrate processing system PS2. Next, in step ST3, the substrate W is transferred from the plasma processing apparatus 1 to the loading port 116 of the liquid processing apparatus 100. Then, the substrate W is transferred to the container 110 and immersed in a processing liquid containing hydrogen fluoride within the container 110. The hydrogen fluoride is supplied to a recess RC formed in a film stack FS of the substrate W. As a result, the side wall SS in the film stack FS is etched in the horizontal direction. During the etching, the temperature of the processing liquid may be maintained at 15° C. to 25° C.

In an embodiment, the substrate W may be transferred from the container 110 to the container 112 and immersed in the rinsing liquid. The substrate W may further be transferred from the container 112 to the container 114 and immersed in the pure water. In an embodiment, the substrate W may be dried in a dryer of the liquid processing apparatus 100. In an embodiment, the substrate W may be transferred to the plasma processing apparatus 1 and dried under a reduced pressure within the plasma processing chamber 10.

Embodiments of the present disclosure further includes the following aspects.

### Appendix 1

An etching method including:
(a) providing a substrate having a film stack including at least two different silicon-containing films and a mask on the film stack;
(b) etching the film stack using plasma generated from a first processing gas to form a recess in the film stack; and
(c) supplying hydrogen fluoride to the recess in the film stack.

### Appendix 2

The etching method of Appendix 1, wherein the film stack includes at least two selected from the group consisting of a silicon oxide film, a silicon nitride film, and a polysilicon film.

### Appendix 3

The etching method of Appendix 1 or 2, wherein the film stack is formed by alternately stacking a silicon oxide film and a silicon nitride film a plurality of times.

### Appendix 4

The etching method of one of Appendices 1 to 3, wherein the mask is a carbon-containing film or a metal-containing film.

### Appendix 5

The etching method of one of Appendices 1 to 4, wherein the first processing gas contains hydrogen fluoride gas.

### Appendix 6

The etching method of one of Appendices 1 to 5, wherein the first processing gas contains at least one gas selected from the group consisting of hydrogen fluoride gas, hydrofluorocarbon gas, and a mixed gas of a hydrogen-containing gas and a fluorine-containing gas.

### Appendix 7

The etching method of one of Appendices 1 to 6, wherein the first processing gas further contains a phosphorus-containing gas.

### Appendix 8

The etching method of one of Appendices 1 to 7, wherein the first processing gas further contains at least one gas selected from the group consisting of a carbon-containing gas, an oxygen-containing gas, and a metal-containing gas.

### Appendix 9

The etching method of one of Appendices 1 to 8, wherein at the end of (b), the recess has a first opening size and a second opening size different from the first opening size alternately along a depth direction of the recess.

### Appendix 10

The etching method of Appendix 9, wherein the difference between the first opening size and the second opening size is 0.2 nm or more.

### Appendix 11

The etching method of one of Appendices 1 to 10, wherein (a) includes disposing the substrate within a first chamber,
(b) includes supplying the first processing gas into the first chamber to generate the plasma, and
(c) includes supplying a second processing gas containing hydrogen fluoride gas into the first chamber.

### Appendix 12

The etching method of Appendix 11, wherein (c) includes:
(c1) controlling aa temperature of the substrate or a substrate support unit that supports the substrate to a first temperature, and controlling a partial pressure of the hydrogen fluoride gas within the chamber to a first pressure; and
(c2) after (c1), controlling the temperature of the substrate or the substrate support unit to a second temperature, and controlling the partial pressure of the hydrogen fluoride gas within the chamber to a second pressure,
wherein the second temperature is higher than the first temperature, and/or the second pressure is lower than the first pressure.

### Appendix 13

The etching method of Appendix 11, wherein (c) includes:
(c1) controlling a temperature of the substrate or a substrate support unit that supports the substrate to a first temperature, and controlling a partial pressure of the hydrogen fluoride gas within the chamber to a first pressure; and
(c2) after (c1), controlling the temperature of the substrate or the substrate support unit to a second temperature, and controlling the partial pressure of the hydrogen fluoride gas within the chamber to a second pressure, and
wherein, in a graph showing an adsorption equilibrium pressure curve of hydrogen fluoride where a horizontal axis represents temperature and a vertical axis represents pressure, the first temperature and the first pressure are located in a first region above the adsorption equilibrium pressure curve, the second temperature and the second pressure are located in a second region below the adsorption equilibrium pressure curve.

### Appendix 14

The etching method of one of Appendices 1 to 10, wherein (a) includes disposing the substrate within a first chamber,
(b) includes supplying the first processing gas into the first chamber to generate the plasma, and
(c) includes transferring the substrate from the first chamber to a second chamber different from the first chamber, and supplying a second processing gas containing hydrogen fluoride gas into the second chamber.

### Appendix 15

The etching method of Appendix 14, wherein (c) includes:
(c1) controlling a temperature of the substrate or a substrate support unit that supports the substrate to a first temperature, and controlling a partial pressure of the hydrogen fluoride gas within the chamber to a first pressure; and
(c2) after (c1), controlling the temperature of the substrate or the substrate support unit to a second temperature, and controlling the partial pressure of the hydrogen fluoride gas within the chamber to a second pressure, and
wherein the second temperature is higher than the first temperature, and/or the second pressure is lower than the first pressure.

### Appendix 16

The etching method of Appendix 14, wherein (c) includes:
(c1) controlling a temperature of the substrate or a substrate support unit that supports the substrate to a first temperature, and controlling a partial pressure of the hydrogen fluoride gas within the chamber to a first pressure; and
(c2) after (c1), controlling the temperature of the substrate or the substrate support unit to a second temperature, and controlling the partial pressure of the hydrogen fluoride gas within the chamber to a second pressure, and
wherein, in a graph showing an adsorption equilibrium pressure curve of hydrogen fluoride where a horizontal axis represents temperature and a vertical axis represents pressure, the first temperature and the first pressure are located in a first region above the adsorption equilibrium pressure curve, the second temperature and the second pressure are located in a second region below the adsorption equilibrium pressure curve.

### Appendix 17

The etching method of one of Appendices 11 to 16, wherein the temperature of the substrate or the substrate support unit that supports the substrate in (c) is controlled to be lower than the temperature of the substrate or the substrate support unit that supports the substrate in (b).

### Appendix 18

The etching method of one of Appendices 11 to 17, wherein the second processing gas further contains a phosphorus-containing gas.

### Appendix 19

The etching method of one of Appendices 1 to 10, wherein (a) includes disposing the substrate within a first chamber,
(b) includes supplying the first processing gas into the first chamber to generate the plasma, and
(c) includes transferring the substrate to the outside of the first chamber, and supplying a processing liquid containing hydrogen fluoride to the substrate from the outside the first chamber.

### Appendix 20

The etching method of Appendix 19, wherein the processing liquid contains hydrofluoric acid (DHF) or buffered hydrofluoric acid (BHF).

### Appendix 21

The etching method of one of Appendices 1to 10, wherein (a) includes disposing the substrate within a first chamber of a plasma processing system,
(b) includes supplying the first processing gas into the first chamber to generate the plasma, and
(c) includes transferring the substrate to a substrate processing apparatus outside the plasma processing system, and supplying hydrogen fluoride to the recess in the film stack within the substrate processing apparatus.

### Appendix 22

The etching method of one of Appendices 1 to 18, further including:
setting conditions of (c) based on data indicating the shape of the recess in the film stack.

### Appendix 23

The etching method of Appendix 22, wherein the conditions include at least one selected from the group consisting of the pressure of the chamber in which the substrate is accommodated, the temperature of the substrate or a substrate support unit that supports the substrate, and the flow rate of the hydrogen fluoride gas.

### Appendix 24

The method of one of appendices 1 to 18, wherein (c) includes:
(c3) supplying the hydrogen fluoride to the recess in the film stack under a first condition; and
(c4) supplying the hydrogen fluoride to the recess in the film stack under a second condition different from the first condition.

### Appendix 25

The etching method of Appendix 24, wherein the second condition is different from the first condition in at least one selected from the group consisting of the pressure of the chamber in which the substrate is accommodated, the temperature of the substrate or a substrate support unit that supports the substrate, and the flow rate of the hydrogen fluoride gas.

### Appendix 26

A plasma processing apparatus having a chamber, a plasma generation unit, a gas supply unit, and a control unit, wherein the control unit is configured to execute:
(a) control to provide the chamber with a substrate having a film stack including at least two different silicon-containing films and a mask on the film stack;
(b) control to etch the film stack using plasma generated from a first processing gas by the plasma generation unit within the chamber to form a recess in the film stack; and
(c) control to supply a second processing gas containing hydrogen fluoride gas to the recess in the film stack by the gas supply unit within the chamber.

### Appendix 27

A substrate processing system having a first chamber, a plasma generation unit, a second chamber, a gas supply unit, and a control unit, wherein the control unit is configured to execute:
(a) control to provide the first chamber with a substrate having a film stack including at least two different silicon-containing films and a mask on the film stack;
(b) control to etch the film stack using plasma generated from a first processing gas by the plasma generation unit within the first chamber to form a recess in the film stack; and
(c) control to transfer the substrate from the first chamber to the second chamber, and supply, within the second chamber, a second processing gas containing hydrogen fluoride gas to the recess in the film stack by the gas supply unit.

### Appendix 28

A substrate processing system including a plasma processing apparatus having a chamber, a plasma generation unit, a liquid processing apparatus, and a control unit, in which the control unit is configured to execute:
(a) control to provide the chamber of the plasma processing apparatus with a substrate having a film stack including at least two different silicon-containing films and a mask on the film stack;
(b) control to etch the film stack using plasma generated from a first processing gas by the plasma generation unit within the chamber to form a recess in the film stack; and
(c) control to transfer the substrate from the chamber to the liquid processing apparatus and supplying a processing liquid containing hydrogen fluoride to the recess in the film stack in the liquid processing apparatus.

### Appendix 29

A device manufacturing method comprising:

(a) providing a substrate having a film stack including at least two different silicon-containing films and a mask on the film stack;
(b) etching the film stack using plasma generated from a first processing gas to form a recess in the film stack; and
(c) supplying hydrogen fluoride to the recess in the film stack.

### Appendix 30

A program that, in a computer of a substrate processing system including a control unit, executes:
(a) control to provide a substrate having a film stack including at least two different silicon-containing films and a mask on the film stack;
(b) control to etch the film stack using plasma generated from a first processing gas to form a recess in the film stack; and
(c) control to supply hydrogen fluoride to the recess in the film stack.

### Appendix 31

A storage medium that stores the program of Appendix 31.

According to an embodiment of the present disclosure, it is possible to provide a technique for suppressing etching shape abnormalities.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) providing a substrate having a film stack including at least two different silicon-containing films and a mask on the film stack;
(b) etching the film stack using plasma generated from a first processing gas to form a recess in the film stack; and
(c) supplying hydrogen fluoride to the recess in the film stack.

2. The etching method according to claim 1, wherein the film stack includes at least two films selected from the group consisting of a silicon oxide film, a silicon nitride film, and a polysilicon film.

3. The etching method according to claim 2, wherein the film stack is formed by alternately stacking a silicon oxide film and a silicon nitride film a plurality of times.

4. The etching method according to claim 1, wherein the mask is a carbon-containing film or a metal-containing film.

5. The etching method according to claim 1, wherein the first processing gas contains hydrogen fluoride gas.

6. The etching method according to claim 1, wherein the first processing gas contains at least one gas selected from the group consisting of hydrogen fluoride gas, hydrofluorocarbon gas, and a mixed gas of a hydrogen-containing gas and a fluorine-containing gas.

7. The etching method according to claim 5, wherein the first processing gas further contains a phosphorus-containing gas.

8. The etching method according to claim 5, wherein the first processing gas further contains at least one gas selected from the group consisting of a carbon-containing gas, an oxygen-containing gas, and a metal-containing gas.

9. The etching method according to claim 1, wherein at the end of (b), the recess has a first opening size and a second opening size different from the first opening size alternately along a depth direction of the recess.

10. The etching method according to claim 9, wherein the difference between the first opening size and the second opening size is 0.2 nm or more.

11. The etching method according to claim 1, wherein (a) includes disposing the substrate within a first chamber,
(b) includes supplying the first processing gas into the first chamber to generate the plasma, and
(c) includes supplying a second processing gas containing hydrogen fluoride gas into the first chamber.

12. The etching method according to claim 11, wherein (c) includes:
(c1) controlling a temperature of the substrate or a substrate support that supports the substrate to a first temperature, and controlling a partial pressure of the hydrogen fluoride gas within the chamber to a first pressure; and
(c2) after (c1), controlling the temperature of the substrate or the substrate support to a second temperature, and controlling the partial pressure of the hydrogen fluoride gas within the chamber to a second pressure, wherein the second temperature is higher than the first temperature, and/or the second pressure is lower than the first pressure.

13. The etching method according to claim 11, wherein (c) includes:
(c1) controlling a temperature of the substrate or a substrate support that supports the substrate to a first temperature, and controlling a partial pressure of the hydrogen fluoride gas within the chamber to a first pressure; and
(c2) after (c1), controlling the temperature of the substrate or the substrate support to a second temperature, and controlling the partial pressure of the hydrogen fluoride gas within the chamber to a second pressure, and wherein, in a graph showing an adsorption equilibrium pressure curve of hydrogen fluoride where a horizontal axis represents temperature and a vertical axis represents pressure, the first temperature and the first pressure are located in a first region above the adsorption equilibrium pressure curve, the second temperature and the second pressure are located in a second region below the adsorption equilibrium pressure curve.

14. The etching method according to claim 1, wherein (a) includes disposing the substrate within a first chamber,
(b) includes supplying the first processing gas into the first chamber to generate the plasma, and
(c) includes transferring the substrate from the first chamber to a second chamber different from the first chamber, and supplying a second processing gas containing hydrogen fluoride gas into the second chamber.

15. The etching method according to claim 14, wherein (c) includes:
(c1) controlling a temperature of the substrate or a substrate support that supports the substrate to a first temperature, and controlling a partial pressure of the hydrogen fluoride gas within the chamber to a first pressure; and
(c2) after (c1), controlling the temperature of the substrate or the substrate support to a second temperature, and controlling the partial pressure of the hydrogen fluoride gas within the chamber to a second pressure, and wherein the second temperature is higher than the first temperature, and/or the second pressure is lower than the first pressure.

16. The etching method according to claim 14, wherein (c) includes:
(c1) controlling a temperature of the substrate or a substrate support that supports the substrate to a first temperature, and controlling a partial pressure of the hydrogen fluoride gas within the chamber to a first pressure; and
(c2) after (c1), controlling the temperature of the substrate or the substrate support to a second temperature, and controlling the partial pressure of the hydrogen fluoride gas within the chamber to a second pressure, and
wherein, in a graph showing an adsorption equilibrium pressure curve of hydrogen fluoride where a horizontal axis represents temperature and a vertical axis represents pressure, the first temperature and the first pressure are located in a first region above the adsorption equilibrium pressure curve, the second temperature and the second pressure are located in a second region below the adsorption equilibrium pressure curve.

17. The etching method according to claim 11, wherein the temperature of the substrate or the substrate support that supports the substrate in (c) is controlled to be lower than the temperature of the substrate or the substrate support that supports the substrate in (b).

18. The etching method according to claim 11, wherein the second processing gas further contains a phosphorus-containing gas.

19. The etching method according to claim 1, wherein (a) includes disposing the substrate within a first chamber,
(b) includes supplying the first processing gas into the first chamber to generate the plasma, and
(c) includes transferring the substrate to the outside of the first chamber, and supplying a processing liquid containing hydrogen fluoride to the substrate from the outside the first chamber.

20. The etching method according to claim 19, wherein the processing liquid contains hydrofluoric acid (DHF) or buffered hydrofluoric acid (BHF).

21. The etching method according to claim 1, wherein (a) includes disposing the substrate within a first chamber of a plasma processing system,
(b) includes supplying the first processing gas into the first chamber to generate the plasma, and
(c) includes transferring the substrate to a substrate processing apparatus outside the plasma processing system, and supplying hydrogen fluoride to the recess in the I film stack within the substrate processing apparatus.

22. The etching method according to claim 1, further comprising:
setting conditions of (c) based on data indicating a shape of the recess in film stack.

23. The etching method according to claim 22, wherein the conditions include at least one selected from the group consisting of a pressure of the chamber in which the substrate is accommodated, a temperature of the substrate or a substrate support that supports the substrate, and a flow rate of the hydrogen fluoride gas.

24. The etching method according to claim 1, wherein (c) includes:
(c3) supplying the hydrogen fluoride to the recess in the film stack under a first condition; and
(c4) supplying the hydrogen fluoride to the recess in the film stack under a second condition different from the first condition.

25. The etching method according to claim 24, wherein the second condition is different from the first condition in at least one selected from the group consisting of a pressure of the chamber in which the substrate is accommodated, a temperature of the substrate or a substrate support that supports the substrate, and a flow rate of the hydrogen fluoride gas.

26. A plasma processing apparatus including a chamber, a plasma generator, a gas supply, and a controller,
wherein the controller is configured to execute a process comprising:
(a) providing a substrate having a film stack including at least two different silicon-containing films and a mask on the film stack;
(b) etching the film stack using plasma generated from a first processing gas to form a recess in the film stack; and
(c) supplying hydrogen fluoride to the recess in the film stack.

27. A substrate processing system including a first chamber, a plasma generator, a second chamber, a gas supply, and a controller,
wherein the controller is configured to execute a process comprising:
(a) providing the first chamber with a substrate having a film stack including at least two different silicon-containing films and a mask on the film stack;
(b) etching the film stack using plasma generated from a first processing gas by the plasma generator within the first chamber to form a recess in the film stack; and
(c) transferring the substrate from the first chamber to the second chamber, and supply, within the second chamber, a second processing gas containing hydrogen fluoride gas to the recess in the film stack by the gas supply.
